(19) United States
(12) Patent Application Publication
(10) Pub. No.: US 2007/0173076 A1
(43) Pub. Date: Jul. 26, 2007

(54) Equipment for sensing malfunctioning roughing valves in an ion implantation apparatus

(76) Inventor: Kyoung-Chon Kim, Gyeonggi-do (KR)

Correspondence Address: LEE & MORSE, P.C., 3141 FAIRVIEW PARK DRIVE, SUITE 500, FALLS CHURCH, VA, 22042, US

(21) Appl. No.: 11/580,919

(22) Filed: Oct. 16, 2006

(30) Foreign Application Priority Data
Jan. 24, 2006 (KR) 2006-0007098

(51) Int. Cl. H01L 21/00

(52) U.S. Cl. 438/800

(57) ABSTRACT

A system for detecting a malfunction of a roughing valve in an ion implantation apparatus, including a valve driving controller, at least one roughing valve having an open-state and a closed-state, at least one solenoid driver electrically connected to the valve driving controller and capable of operating the roughing valve, at least one sensor electrically connected to the valve driving controller, the sensor being capable to determine a state of the roughing valve, a first relay activated by the sensor in response to the state of the roughing valve to transmit a signal, and a main controller electrically connect to the first relay to respond to the transmitted signal.

### BACKGROUND OF THE INVENTION

1. Field of the Invention

The present invention relates to equipment capable of detecting malfunctioning units in a semiconductor manufacturing process. In particular, the present invention relates to a system capable of detecting malfunctioning roughing valves in an ion implantation apparatus during an ion implantation process.

2. Description of the Related Art

In general, an ion implantation process may refer to a process of converting an N-type impurity, i.e., a semiconductor dopant having five valance electrons, such as antimony (Sb), phosphorus (P), arsenic (As), and so forth, or a P-type impurity, i.e., a semiconductor dopant having three valance electrons, such as boron (B), aluminum (Al), indium (In), and so forth, into ions and depositing them into a silicon wafer by way of an ion beam, thereby improving the conductivity and resistance of the silicon wafer.

An ion implantation apparatus may adjust more accurately ion implantation, i.e., impurities, depth and concentration in a wafer, as compared to other impurity implantation technologies such as diffusion. For example, the ion implantation apparatus may implant impurities in a wafer within a concentration range of from about 10E14 to about 10E18 atoms/cm³.

A conventional ion implantation apparatus may include an ion source chamber, a beam line chamber forming a beam of ions, an end station implanting the ions into a wafer, at least one load-lock chamber for carrying wafers into and out of the end station, and a plurality of valves, e.g., solenoid valves, and pumps, e.g., turbo-pumps, cryogenic pumps, and so forth, for supplying vacuum environment into the end station during the ion implantation process.

However, when a solenoid valve malfunctions, a pressure difference may be created between the different process chambers, e.g., between the load-lock chamber and the end station, thereby increasing the temperature of the cryogenic pump(s) supplying vacuum environment to the end station. Temperature increase of the cryogenic pump may trigger its temporary inability to pump, and, subsequently, cause potential failure of other vacuum pumps and a vacuum trip in the apparatus, thereby generating an overall process failure. Therefore, there exists a need for semiconductor equipment capable of detecting malfunctioning roughing valves in an ion implantation apparatus.

### SUMMARY OF THE INVENTION

The present invention is therefore directed to equipment capable of detecting malfunctioning roughing valves in an ion implantation apparatus, which substantially overcomes one or more of the problems due to the limitations and disadvantages of the related art.

It is therefore a feature of an embodiment of the present invention to provide a system capable of detecting malfunctioning roughing valves in an ion implantation apparatus, and, subsequently, generate a system interlock to minimize process failure.

At least one of the above and other features and advantages of the present invention may be realized by providing a system for detecting malfunctioning roughing valves in an ion implantation apparatus, including a valve driving controller, at least one roughing valve having an open-state and a closed-state, at least one solenoid driver electrically connected to the valve driving controller and capable of operating the roughing valve, at least one sensor connected to the valve driving controller and capable of determining a state of the roughing valve, a first relay activated by the sensor to transmit a signal in response to the state of the roughing valve, and a main controller electrically connect to the first relay to respond to the transmitted signal.

The first relay may be activated in response to the open-state of the roughing valve. The sensor may include a first sensor arm and a second sensor arm. The roughing valve may include a plunger.

The system in accordance with an embodiment of the present invention may further include a second relay activated by the sensor to transmit a signal in response to the closed-state of the roughing valve. The system may also include a display unit to indicate a closed-state, and the display unit may include at least one LED.

In another aspect of the present invention, there is provided a system for detecting a malfunction of a roughing valve in an ion implantation apparatus, including a valve driving controller, a main controller, a plurality of relays, a plurality of solenoid drivers, a plurality of roughing valves, and a plurality of sensors. Preferably, the system may include first to fifth solenoid drivers, first to fifth roughing valves, first to fifth sensors, and first to fourth relays.

The third relay may be activated by the second sensor to transmit a signal in response to the open-state of the second roughing valve and the fourth relay may be activated by the second sensor to transmit a signal in response to the closed-state of the second sensor.

Each of the first to fifth sensors may include a first sensor arm and a second sensor arm. Each of the first to fifth roughing valves may include a plunger.

The system may further include a first LED and a second LED.

### BRIEF DESCRIPTION OF THE DRAWINGS

The above and other features and advantages of the present invention will become more apparent to those of ordinary skill in the art by describing in detail exemplary embodiments thereof with reference to the attached drawings, in which:

FIG. 1 illustrates a configuration of an ion implantation apparatus according to an embodiment of the present invention;

FIG. 2 illustrates a block diagram of a system for detecting malfunctioning roughing valves according to an embodiment of the present invention;

FIG. 3 illustrates operation of the first and second sensors 132 and 134 of FIG. 2; and

FIG. 4 illustrates operation of the third, fourth, and fifth sensors 136, 138, and 140 of FIG. 2.

### DETAILED DESCRIPTION OF THE INVENTION

Korean Patent Application No. 10-2006-0007098, filed Jan. 24, 2006, in the Korean Intellectual Property Office, and entitled: “Equipment for Sensing Malfunction of Roughing Valve in Ion Implantation Apparatus,” is incorporated by reference herein in its entirety.

The present invention will now be described more fully hereinafter with reference to the accompanying drawings, in which exemplary embodiments of the invention are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the figures, the dimensions of layers and regions are exaggerated for clarity of illustration.

It will also be understood that when an element is referred to as being “on” another element or substrate, it can be directly on the other element or substrate, or intervening elements may also be present. Further, it will be understood that when an element is referred to as being “under” another element, it can be directly under, or one or more intervening elements may also be present. In addition, it will also be understood that when an element is referred to as being “between” two elements, it can be the only element between the two elements, or one or more intervening elements may also be present. Like reference numerals refer to like elements throughout.

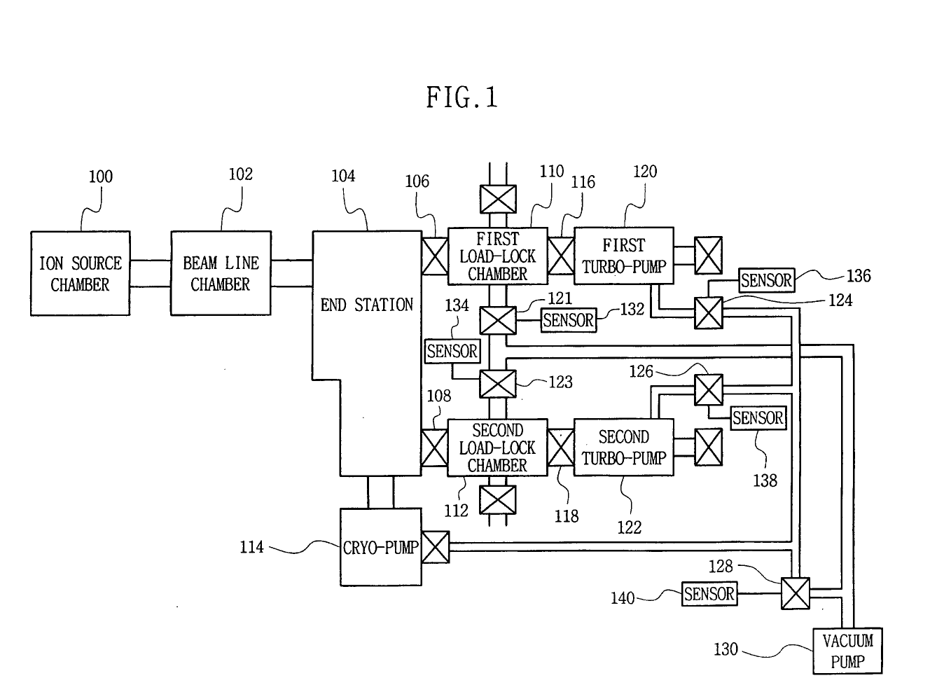

An exemplary embodiment of an ion implantation apparatus and its operation according to the present invention is more fully described below with reference to FIG. 1.

As illustrated in FIG. 1, an ion implantation apparatus according to an embodiment of the present invention may include an ion source chamber 100 to produce impurity ions from a source substance, a beam line chamber 102 to form a beam of ions to be implanted into a wafer, an end station 104 to implant the ion beam into a wafer, first and second load-lock chambers 110 and 112 to carry a wafer(s) into and out of the end station 104 to be ion-implanted, first and second turbo-pumps 120 and 122 to provide high-vacuum environment to the first and second load-lock chambers 110 and 112, respectively, a vacuum pump 130 to support the first and second turbo-pumps 120 and 122, a cryogenic pump (cryo-pump) 114 to maintain high vacuum state in the end station 104, and a plurality of valves.

In particular, as further illustrated in FIG. 1, the ion implantation apparatus according to an embodiment of the present invention may include first to fourth isolation valves 106, 108, 116, and 118, respectively, to separate the first and second load-lock chambers 110 and 112 from adjacent units, i.e., end station 104 and first and second turbo-pumps 120 and 122, first to fifth roughing valves 121, 123, 124, 126, and 128, respectively, to open/close the vacuum lines leading to the first and second load-lock chambers 110 and 112, first and second turbo-pumps 120 and 122, and the cryo-pump 114, and first to fifth sensors 132, 134, 136, 138, and 140, respectively, to sense the states of the first to fifth roughing valves 121, 123, 124, 126, and 128, respectively.

The first and second isolation valves 106 and 108 may be installed between the end station 104 and the first load-lock chamber 110 and between the end station 104 and the second load-lock chamber 112, respectively. The third and fourth isolation valves 116 and 118 may be installed between the first load-lock chamber 110 and the first turbo-pump 120 and between the second load-lock chamber 112 and the second turbo-pump 122, respectively.

The first to fifth roughing valves 121, 123, 124, 126, and 128 may be solenoid valves having an “open-state” and a “closed-state.” In this respect is should be noted that an “open-state” and a “closed-state” with respect to embodiments of the present invention refer to respective states at which a roughing valve is fully open by a solenoid driver for the purpose of fluid transfer and a state at which a roughing valve is fully closed by a solenoid driver such that no fluid can pass through.

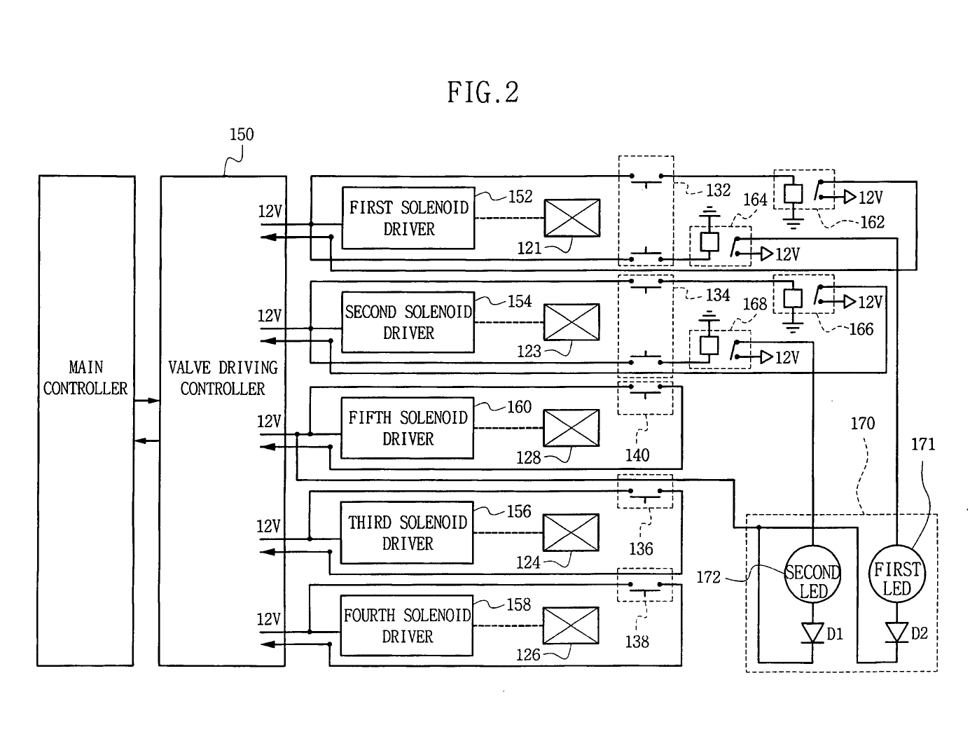

As further illustrated in FIG. 1, the first and second roughing valves 121 and 123 may be installed on the vacuum lines connecting the vacuum pump 130 to the first and second load-lock chambers 110 and 112, respectively, thereby controlling vacuum and atmospheric pressure supply to the first and second load-lock chambers 110 and 112, respectively. The third and fourth roughing valves 124 and 126 may be installed on the vacuum lines connecting the first and second turbo-pumps 120 and 122 to the cryo-pump 114 and fifth roughing valve 128, thereby controlling support of vacuum pumping to the first and second turbo-pumps 120 and 122, respectively. The fifth roughing valve 128 may be installed on the vacuum line connecting the vacuum pump 130 to the first and second turbo-pumps 120 and 122 and to the cryo-pump 114, thereby controlling support of vacuum pumping through vacuum pump 130. Each of the first to fifth sensors 132, 134, 136, 138, and 140 may be correspond to a first to fifth roughing valve 121, 123, 124, 126, or 128 to monitor its operation, i.e. its open/closed-state. The mechanism monitoring the operation of the roughing valves 121, 123, 124, 126, and 128, will be discussed in more detail with respect to FIG. 2.

As illustrated in FIG. 2, an exemplary system for detecting malfunctioning roughing valves according to an embodiment of the present invention may include a main controller 190, a valve driving controller 150 to generate driving voltages by means of desired control signals (not shown), first to fifth roughing valves 121, 123, 124, 126, and 128, first to fifth solenoid drivers 152, 154, 156, 158, and 160 to open/close the first to fifth roughing valves 121, 123, 124, 126, and 128, first to fifth sensors 132, 134, 136, 138, and 140, a first and second relay 162 and 164 to sense the open/closed-states, respectively, of the first roughing valve 121, a third and fourth relay 166 and 168 to sense the open/closed-states, respectively, of the second roughing valve 123, and a display unit 170 including a first and second light emitting diodes (LED) 171 and 172.

In particular, the valve driving controller 150 may generate a control signal of about 12 V for each of the solenoid drivers 152, 154, 156, 158, and 160 to provide sufficient voltage to open the first to fifth roughing valves 121, 123, 124, 126, and 128, respectively. When the valve driving controller 150 stops applying a voltage of 12 V to either of the solenoid drivers 152, 154, 156, 158, and 160, the corresponding roughing valves may be closed. Accordingly, the main controller 190 connected to the valve driving controller 150 may determine a desired state of a roughing valve based on the control signal, i.e., an output of 12 V signal may indicate an open valve(s) to the main controller 190, and lack of an output of 12 V signal may indicate a closed valve(s) to the main controller 190.

Each solenoid driver 152, 154, 156, 158, and 160 may be connected to the valve driving controller 150 on one side and to the roughing valve 121, 123, 124, 126, and 128, respectively, on the other side, such that each one of the solenoid drivers 152, 154, 156, 158, and 160 may be in electric communication with the valve driving controller 150 and in fluid communication with a corresponding roughing valve 121, 123, 124, 126, or 128 via air lines. Accordingly, the control signal from the valve driving controller 150 to the solenoid drivers 152, 154, 156, 158, and 160 may supply/interrupt sufficient air flow to provide a predetermined amount of pressure to open/close, respectively, the roughing valves 121, 123, 124, 126, and 128, such that each solenoid driver may open/close its corresponding roughing valve.

Therefore, the first to fifth roughing valves 121, 123, 124, 126, and 128 may open/close with respect to the air supplied from the first to fifth solenoid drivers 152, 154, 156, 158, and 160. The first to fifth sensors 132, 134, 136, 138, and 140, which may correspond to each of the first to fifth roughing valves 121, 123, 124, 126, and 128, may sense the open/closed-state of each roughing valve, and, consequently, activate a corresponding relay to transmit an open/close signal by way of the valve driving controller 150 to the main controller 190. In this respect is should be noted that an “open/close signal” refers to a 12 V pulse generated by the valve driving controller 150 or by a power supply adaptor 195. In particular, when an open-state of a valve is determined, the 12 V pulse may be transmitted through a relay into the valve driving controller 150, thereby indicating an “open signal.” Alternatively, when a closed-state of a valve is determined, the 12 V pulse may be transmitted through a relay to the display unit 170, thereby indicating a “close signal.”

In detail, the first relay 162 may be activated by a first sensor 132 as a result of sensing that the first roughing valve 121 is at an open-state. The first relay 162 may transmit the open signal to the valve driving controller 150. The second relay 164 may be activated by the first sensor 132 as a result of sensing that the first roughing valve 121 is at a closed-state. The second relay 164 may transmit the close signal, to the LED 171.

Similarly, the third relay 166 may be activated by the second sensor 134 as a result of sensing that the second roughing valve 123 is at an open-state. The third relay 166 may transmit an open signal to the valve driving controller 150. The fourth relay 168 may be activated by the second sensor 134 as a result of sensing that the second roughing valve 123 is at a closed-state. The fourth relay 168 may transmit the close signal with respect to the second roughing valve 123 to the LED 172.

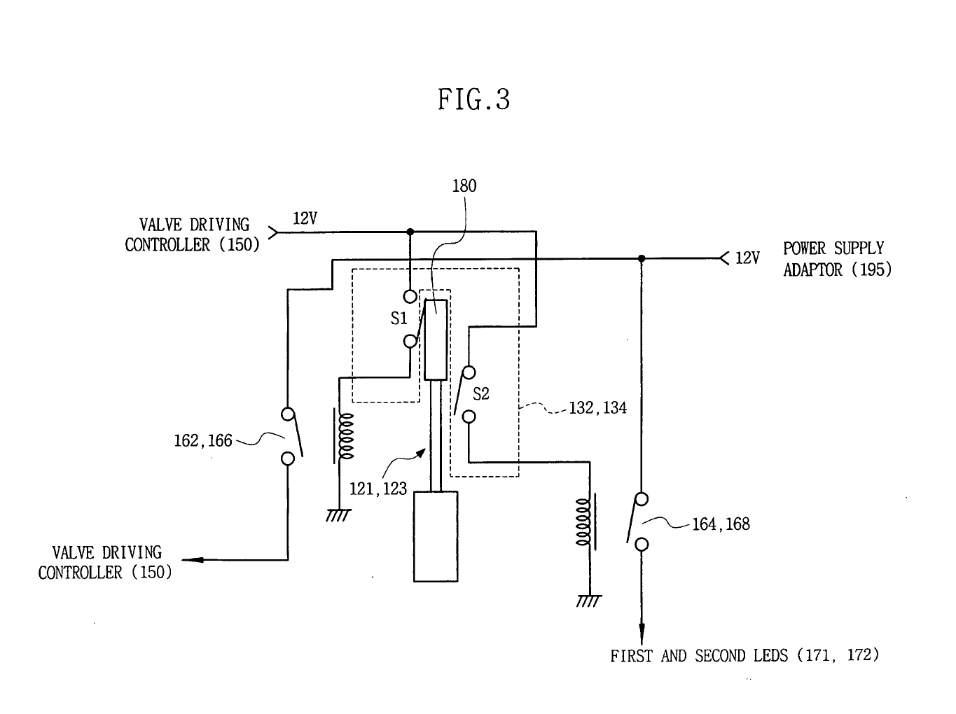

Operation of the first and second sensors 132 and 134 according to an embodiment of the present invention is illustrated with respect to FIG. 3. As discussed previously with respect to FIG. 2, the first and second sensors 132 and 134 may sense the open/closed-state of each first and second roughing valve 121 and 123, and, consequently, activate a corresponding relay to transmit an open/close signal.

In particular, when the first and/or second roughing valves 121 and 123 are open, a plunger 180 of each of the first and second roughing valves 121 and 123 may be raised to activate a first sensor arm S1 of the first and second sensors 132 and 134, i.e., close a circuit, such that current may flow through the first sensor arm S1 and a solenoid, as illustrated in FIG. 3. When the first sensor arm S1 is activated, the first and third relays 162 and 166 may be activated as well, thereby facilitating passage of the 12 V pulse, i.e., open signal, from the power supply adaptor 195 through the first and third relays 162 and 166 into the valve driving controller 150. The transmittance of an open signal into the valve driving controller 150 may be compared to the control signal generated by the valve driving control 150. In particular, a determination of the main controller 190 that a control signal generated by the valve driver controller 150 for opening the first and second roughing valves 121 and 123 corresponds to the transmitted open signal may indicate that the first and second roughing valves 121 and 123 are at open operational state, i.e. the first and second roughing valves 121 and 123 may be open in response to the operation of the main controller 190. In this case, the main controller 190 may respond by proceeding ion implantation operation.

However, when the control signal of the valve driver controller 150 does not correspond to the open signal, i.e., when the valve driver controller generates a control signal to open the first and/or second roughing valves 121 and 123, but an open signal is not transmitted to the valve driving controller 150, the main controller 190 may determine that the first roughing valve 121 may be at a malfunctioned state. Consequently, the main controller 190 may respond by generating an interlock to pause the operation of the ion implantation apparatus.

Similarly, when the first and/or second roughing valves 121 and 123 are closed, the plunger 180 of each of the first and second roughing valves 121 and 123 may be lowered to activate a second sensor arm S2 of the first and second sensors 132 and 134, i.e., close a circuit, such that current may flow through the second sensor arm S2 and the solenoid, as illustrated in FIG. 3. When the second sensor arm S2 is activated, the second and fourth relays 164 and 168 may be activated as well, thereby facilitating passage of a close signal from the power supply adaptor 195 through the second and fourth relays 164 and 168 to the first and second LEDs 171 and 172. Lighting of the first and second LEDs 171 and 172 may indicate that the first and second roughing valves 121 and 123 are at closed-state.

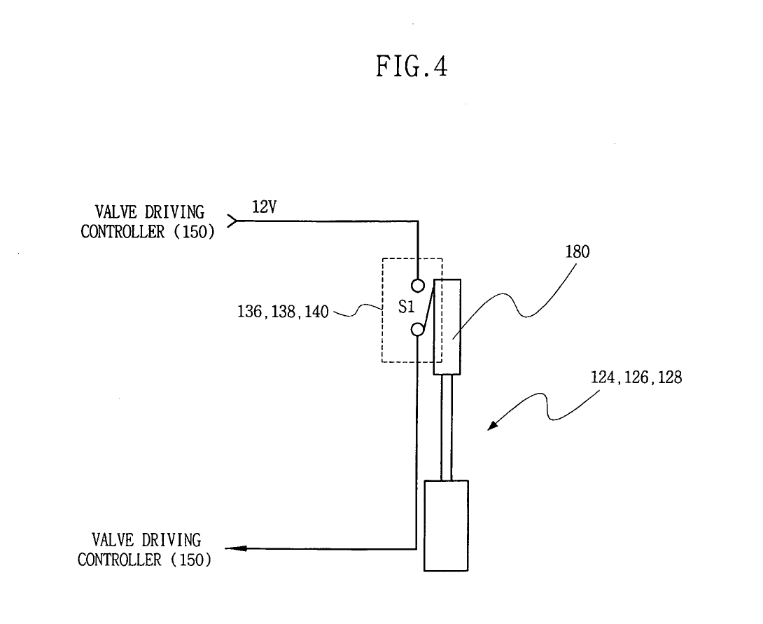

The system for detecting malfunctioning roughing valves according to an embodiment of the present invention may also include a third, fourth, and fifth sensors 136, 138, and 140, and their activation is illustrated with respect to FIG. 4. The third, fourth, and fifth sensors 136,138, and 140 may sense an open-state of each third, fourth, and fifth roughing valves 124, 126, and 128, and, consequently, activate a corresponding relay to transmit an open signal to the main controller 190.

In particular, when the third, fourth, and fifth roughing valves 124, 126, and 128 are open, a plunger 180 of each of the third, fourth, and fifth roughing valves 124, 126, and 128 may be raised to activate the first sensor arm S1 of the third, fourth, and fifth sensors 136, 138, and 140. When the first sensor arm S1 is activated, an open signal from the valve driving controller 150 may be fed back into the valve driving controller 150 through driving controller 150 may be compared to the control signal generated by the valve driving control 150. In particular, a determination of the main controller 190 that a control signal generated by the valve driver controller 150 for opening the first and second roughing valves 121 and 123 corresponds to the transmitted open signal may indicate that third, fourth, and fifth roughing valves 124, 126, and 128 are at open operational state, i.e. the third, fourth, and fifth roughing valves 124, 126, and 128 may be open in response to the operation of the main controller 190. In this case, the main controller 190 may respond by proceeding ion implantation operation.

However, when the control signal of the valve driver controller 150 does not correspond to the open signal, i.e., when the valve driver controller 150 generates a control signal to open the third, fourth, or fifth roughing valves 124, 126, and 128, but an open signal is not transmitted to the valve driving controller 150, the main controller 190 may determine that the corresponding third, fourth, or fifth roughing valves 124, 126, and 128, respectively, may be at a malfunctioned state. Consequently, the main controller 190 may respond by generating an interlock to pause the operation of the ion implantation apparatus.

The display unit 170 of the system for detecting malfunctioning roughing valves may include diodes D1 and D2. The diodes D1 and D2 may be installed at rear terminals of the first and second LEDs 171 and 172, respectively, in order to prevent a backward flow of the close signal by the valve driving controller 150 in order to drive the fifth solenoid driver 160.

An operation of the ion implantation apparatus according to an embodiment of the present invention may include transfer of wafers into the first and second load-lock chambers 110 and 112, and, subsequently, loading the wafers into or out of the end station 104 for ion implantation. It should be noted that the wafer implantation may be performed at a high vacuum state, thereby requiring transferring and loading the wafers at a high vacuum state as well, i.e., converting the atmospheric pressure state of the first and second load-lock chambers 110 and 112 into a high vacuum state to correspond to the vacuum state of the end station 104. The process of achieving high vacuum state in the apparatus units of an embodiment of the present invention may require control of the first to fifth roughing valves-121, 123, 124, 126, and 128 in order to achieve the required vacuum state in the first and second load-lock chambers 110 and 112, as will be described in more detail with respect to FIGS. 1-4.

First, the main controller 190 may control the valve driving controller 150 in order to maintain the first load-lock chamber 110 at a high vacuum state. In particular, the valve driving controller 150 may drive the first solenoid driver 152 to open the first roughing valve 121 and drive the second and fifth solenoid drivers 154 and 160 to close the second and fifth roughing valves 123 and 128. As such, the only open vacuum line may be between the vacuum pump 130 and the first load-lock chamber 110 through roughing valve 121, as can be seen in FIG. 1

When the valve driving controller 150 supplies voltage to the first solenoid driver 152, the first solenoid driver 152 may supply air to the first roughing valve 121 through an air line to open the first roughing valve 121. Subsequently, the main controller 190 may drive the vacuum pump 130 to depressurize the first load-lock chamber 110 of an atmospheric pressure state, e.g., provide pressure of about 10⁻³ torr in the first load-lock chamber 110.

Opening of the first roughing valve 121, as discussed previously with respect to FIG. 2, may raise the plunger 180 of the first roughing valve 121 to activate the first sensor arm S1 of the first sensor 132, thereby transmitting the open signal and turning on the first relay 162 to transfer an open signal from the power supply adaptor 195 to the valve driving controller 150 to indicate open operational state of the first roughing valve 121.

Alternatively, closing the second roughing valve 123 may lower the plunger 180 of the second roughing valve 123 to activate the second sensor arm S2 of the second sensor 134, thereby transmitting the closed signal and turning on the fourth relay 168 to transfer a voltage of 12 V from the power supply adaptor 195 to the second LED 172 to closed-state of the second roughing valve 123.

It should be noted, however, that the pressure in the end station 104 may be lower than about 10⁻³ torr. However, the vacuum pump 130 may not be capable to depressurize the first load-lock chamber 110 to the same pressure as that of the end station 104, thereby requiring additional depressurizing by the first turbo-pump 120.

Accordingly, when the pressure of the first load-lock chamber 110 is lowered up to about 10⁻³ torr, the main controller 190 may control the valve driving controller 150 to close the first roughing valve 121 and open the third isolation valve 116, and the third and fifth roughing valves 124 and 128. As such, the only open vacuum line may be between the vacuum pump 130 and the first load-lock chamber 110 through the first turbo-pump 120 and the corresponding third and fifth roughing valves 124 and 128, as can be seen in FIG. 1

Subsequently, the main controller 190 may drive the first turbo-pump 120 to depressurize the first load-lock chamber 110 to reach a high vacuum state, e.g., about 10⁻⁴ torr, thereby equalizing the pressure inside the first load-lock chamber 110 and the end station 104. Once an equal pressure state is achieved, the first isolation valve 106 may be opened, and the wafer located inside the first load-lock chamber 110 may be transferred into the end station 104. Constant high vacuum state may be maintained inside the end station 104 during an ion implantation process by the cryo-pump 114.

Similar operation of valves and pumps may be performed with respect to the second load-lock chamber. The main controller 190 may control the valve driving controller 150 in order to maintain the second load-lock chamber 112 at a high vacuum state. In particular, the valve driving controller 150 may drive the second solenoid driver 154 to open the second roughing valve 123 and drive the first and fifth solenoid drivers 152 and 160 to close the first and fifth roughing valves 121 and 128. As such, the only open vacuum line may be between the vacuum pump 130 and the second load-lock chamber 112 through roughing valve 123, as can be seen in FIG. 1

Next, the main controller 190 may drive the vacuum pump 130 to depressurize the second load-lock chamber 112 of an atmospheric pressure state, e.g., provide pressure of about 10⁻³ torr in the second load-lock chamber 112. Since the vacuum pump 130 may not be capable to depressurize the second load-lock chamber 112 to a pressure below about 10⁻³ torr, the main controller 190 may control the valve driving controller 150 to close the second roughing valve 123 and open the fourth isolation valve 118, and the fourth and fifth roughing valves 126 and 128. As such, the only open vacuum line may be between the vacuum pump 130 and the second load-lock chamber 112 through the second turbo-pump 122 and the corresponding fourth and fifth roughing valves 126 and 128, as can be seen in FIG. 1.

Subsequently, the main controller 190 may drive the second turbo-pump 122 to depressurize the second load-lock chamber 112 to reach a high vacuum state, e.g., about 10⁻⁴ torr, thereby equalizing the pressure inside the first load-lock chamber 112 and the end station 104. Once an equal pressure state is achieved, the second isolation valve 118 may be opened, and the wafer located inside the second load-lock chamber 112 may be transferred into the end station 104. Constant high vacuum state may be maintained inside the end station 104 during an ion implantation process by the cryo-pump 114.

Exemplary embodiments of the present invention have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A system for detecting malfunctioning roughing valves in an ion implantation apparatus, comprising:
a valve driving controller;
at least one roughing valve having an open-state and a closed-state;
at least one solenoid driver electrically connected to the valve driving controller and capable of operating the roughing valve;
at least one sensor connected to the valve driving controller and capable of determining a state of the roughing valve;
a first relay activated by the sensor to transmit a signal to the valve driving controller in response to the state of the roughing valve; and
a main controller electrically connected to the valve driving controller to respond to the transmitted signal.

2. The system as claimed in claim 1, wherein the first relay is activated in response to the open-state of the roughing valve.

3. The system as claimed in claim 2, further comprising a second relay activated by the sensor to transmit a signal in response to the closed-state of the roughing valve.

4. The system as claimed in claim 3, further comprising a display unit to indicate a closed-state.

5. The system as claimed in claim 4, wherein the display unit comprises at least one LED.

6. The system as claimed in claim 1, wherein the sensor comprises a first sensor arm and a second sensor arm.

7. The system as claimed in claim 6, wherein the roughing valve comprises a plunger.

8. The system as claimed in claim 3, further comprising a plurality of solenoid drivers, a plurality of roughing valves, and a plurality of sensors.

9. The system as claimed in claim 8, wherein the plurality of solenoid drives comprises a first, second, third, fourth, and fifth solenoid drivers, the plurality of roughing valves comprises a first, second, third, fourth, and fifth roughing valves, and the plurality of sensors comprises a first, second, third, fourth, and fifth sensors.

10. The system as claimed in claim 9, further comprising a third relay activated by the second sensor to transmit a signal in response to the open-state of the second roughing valve and a fourth relay activated by the second sensor to transmit a signal in response to the closed-state of the second sensor.

11. The system as claimed in claim 10, further comprising a first LED and a second LED.

12. The system as claimed in claim 10, wherein each of the first to fifth sensors comprises at least a first sensor arm.

13. The system as claimed in claim 12, wherein each of the first to fifth roughing valves comprises a plunger.
